(19) United States
(12) Patent Application Publication
(10) Pub. No.: US 2013/0162277 A1
(43) Pub. Date: Jun. 27, 2013

(54) UNIFORM FIELD AREA TESTING APPARATUS AND TESTING METHOD USING SAME

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventor: XIAO-LIAN HE, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/718,218

(22) Filed: Dec. 18, 2012

(30) Foreign Application Priority Data
Dec. 27, 2011 (CN) 201110443664.1

(51) Int. Cl. G01R 1/04; G01R 1/07

(52) U.S. Cl. CPC G01R 1/0408; G01R 1/07
USPC 324/754.21; 324/756.03

(57) ABSTRACT

A uniform field area (UFA) testing apparatus, used for an UFA test, including a testing rack and a plurality of field strength probes. The plurality of field strength probes are mounted on the testing rack. The plurality of field strength probes are positioned on a vertical plane and forms a probe grid array corresponding to the testing points of the UFA test, the grid spacing of the probe grid array corresponds to the distance of the neighboring testing points of the UFA test.

### BACKGROUND

1. Technical Field

The present disclosure relates to electromagnetic field testing apparatus and method, and particularly to a uniform field area (UFA) testing apparatus and testing method using the same.

2. Description of Related Art

Before a radiation, radio-frequency, electromagnetic field immunity test of an electromagnetic compatibility (EMC) test can be conducted, the field area used in the test should be verified first, to ensure the electromagnetic field strength is substantial uniformity in this field area. The field area about to be verified the uniformity is usually called a uniform field area (UFA). Typically, the size of the UFA is a plane area of 1.5 meters×1.5 meters, and includes 16 testing points equally spaced on the UFA. The spacing between two neighboring testing points is 0.5 m. When test for a UFA, a field strength probe is placed on one of the testing points, and a signal generator, a power amplifier, and an emission antenna transmit signals in different frequencies and different antenna polarities for the test. The field strength probe receives the signals at a point, and measures the field strength at that point. After measuring the field strength at a testing point, the field strength probe should be moved to another testing point, and each step of the abovementioned test repeated. Finally, collecting the field strength measurements of all the testing points, and evaluating the field strength uniformity of the UFA must be done. However, physically adjusting the antenna polarity and frequencies of the signals for the field strength probe at each point of test is time-consuming and inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a UFA testing apparatus.

FIG. 2 is an isometric view of the UFA testing apparatus used in UFA tests.

FIG. 3 is a schematic functional diagram of a UFA testing system using the UFA testing apparatus shown in FIG. 1.

FIG. 4 is a flow chart of a UFA testing method applied by the UFA testing apparatus.

FIG. 5 shows sub-steps of one step of the UFA testing method of FIG. 4.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one”.

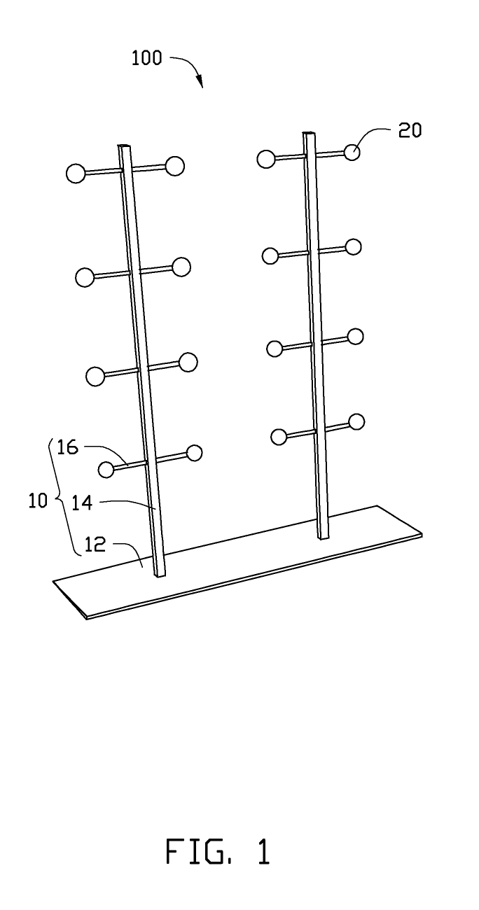

FIG. 1 is an assembled, isometric view of an exemplary embodiment of a UFA testing apparatus 100. The UFA testing apparatus 100 includes a testing rack 10 and a plurality of field strength probes 20. The field strength probes 20 are detachably mounted on the testing rack 10. In the present embodiment, the testing rack 10 includes a baseboard 12, two columns 14, and several bars 16. The baseboard 12 is horizontal. The two columns 14 are mounted on the baseboard 12 and are perpendicular to the baseboard 12. The several bars 16 are mounted so as to be spaced apart on the two columns 14, and are perpendicular to the column 14. The distal ends of each bar 16 hold a detachable field strength probe 20. The several bars 16 are equally spaced on the column 14 at a predetermined distance, e.g. 0.5 m, with the lowest bars 16 being a predetermined height of 0.8 m above the floor, so that the field strength probes 20 on the testing rack 10 are positioned on a vertical plane, and form a probe grid array with an area of 1.5 m×1.5 m, with a grid spacing of 0.5 m, and a lower edge of the probe grid array at a height of 0.8 m above the floor to corresponding the predetermined testing points of the UFA.

The testing rack 10 can also include four columns 14, and the field strength probes 20 can be directly arranged on the column 14 of the testing rack 10 to form the probe grid array. The testing rack 10 can also be other structures, on condition that the field strength probes 20 arranged on the testing rack 10 must always be able to form the probe grid array corresponding to the predetermined testing points of the UFA test.

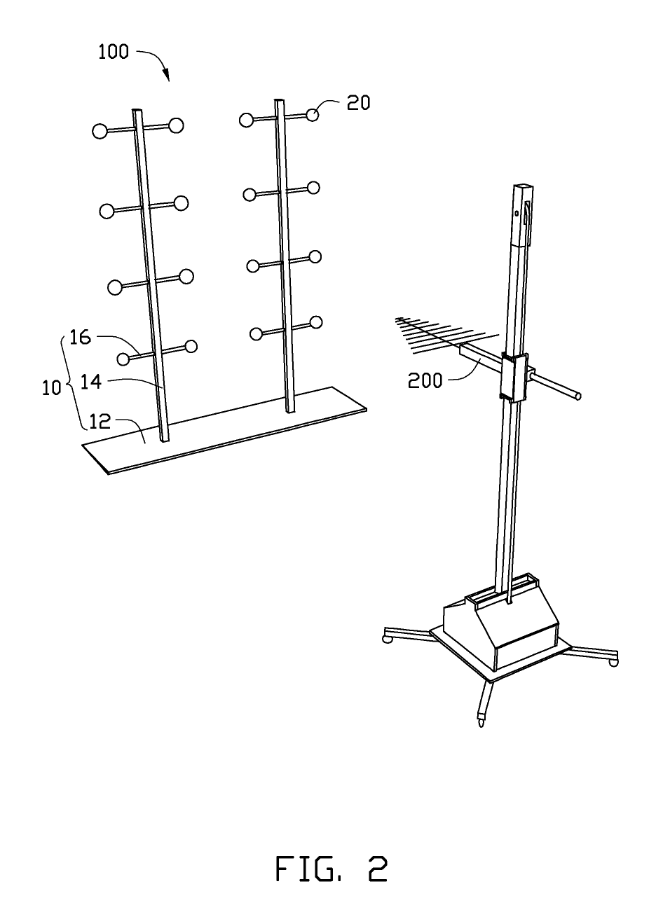

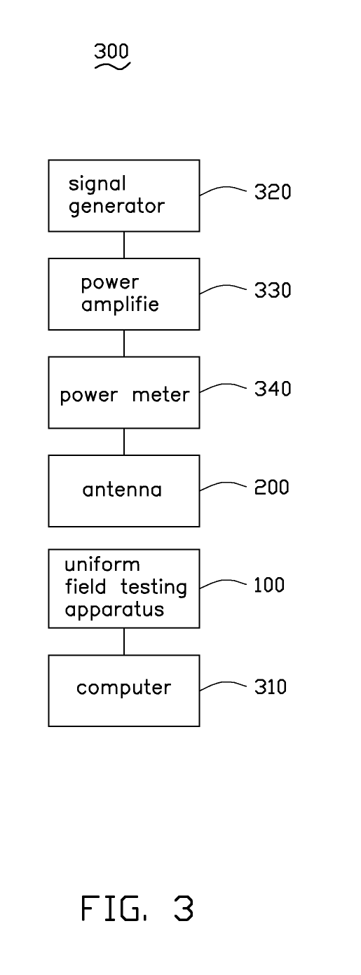

FIG. 2 is an isometric view of the UFA testing apparatus 100 used for UFA testing. FIG. 3 is a plan view of a UFA testing system 300 with the UFA testing apparatus 100 shown in FIG. 1. Referring to FIG. 2 and FIG. 3, the UFA testing system 300 includes a UFA testing apparatus 100, an antenna 200, a computer 310, a signal generator 320, a power amplifier 330, and a power meter 340. The UFA testing apparatus 100 is connected to the computer 310. The computer 310 records, displays and analyzes the data transmitted from the field strength probes 20. The signal generator 320, the power amplifier 330, the power meter 340, and the antenna 200 are electrically powered. The antenna 200 is aimed at the UFA testing apparatus 100, and transmits signals created by the signal generator 320, the power amplifier 330, and the power meter 340. The antenna 200 is a predetermined distance from the UFA testing apparatus 100. The distance between the antenna 200 and UFA testing apparatus 100 is preferred to be 3 m. The antenna 200 is a dual polarization antenna that can transmit signals in different polarizations, i.e., a horizontal polarization and a vertical polarization.

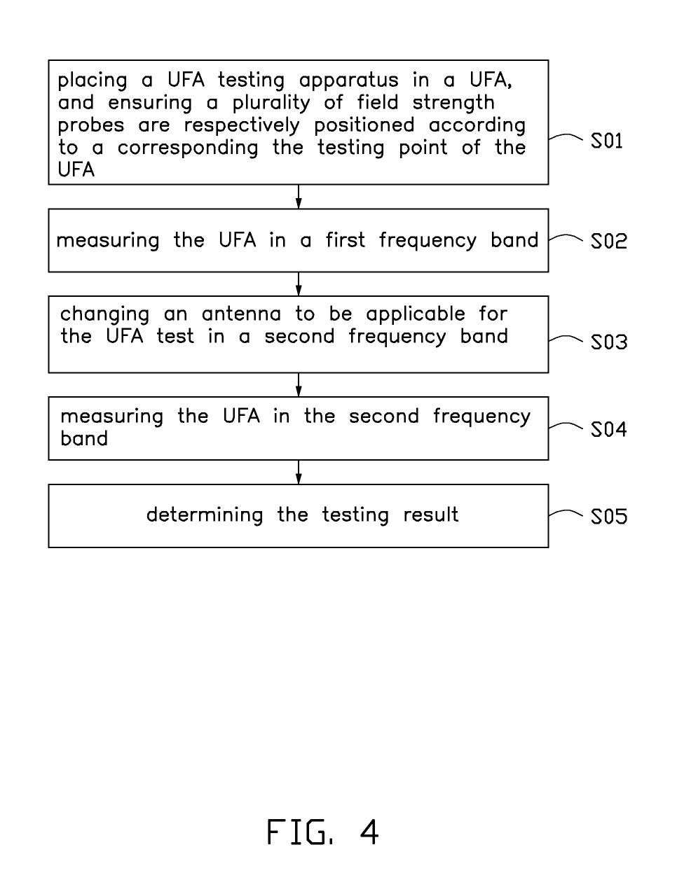

FIG. 4 is a flow chart of a UFA testing method using the UFA testing apparatus 100. The UFA testing method includes the following steps:

Step 01, placing the UFA testing apparatus 100 for testing, and ensuring that the field strength probes 20 are each positioned corresponding to UFA testing points. The UFA testing apparatus 100 is placed a predetermined distance from the antenna 200 of the UFA testing system 300, and both of the UFA testing apparatus 100 and the antenna 200 are placed into an electromagnetic anechoic chamber (not shown).

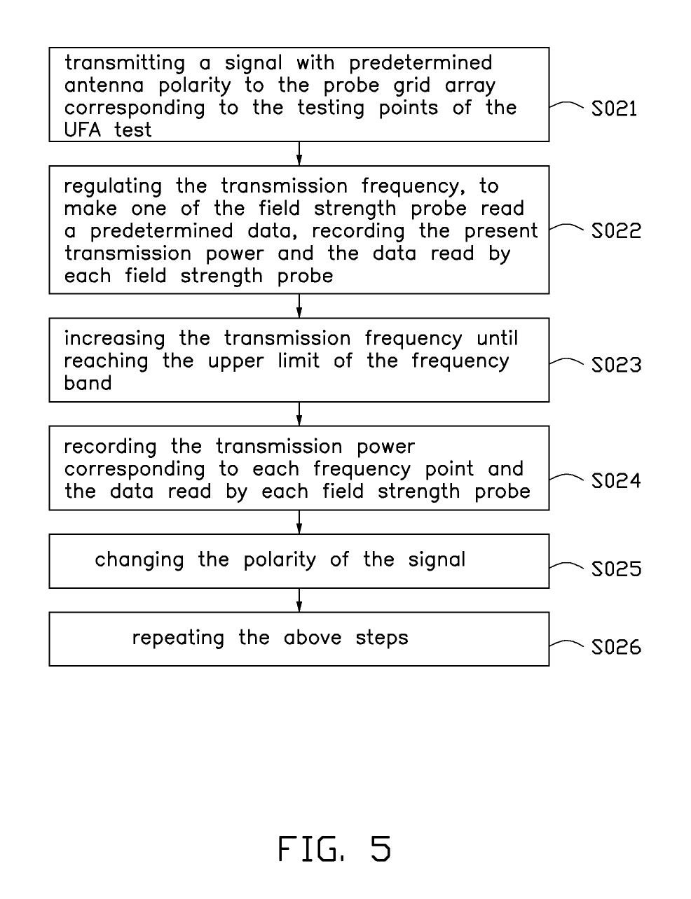

Step 02, measuring a first frequency band of the UFA. Specifically, referring to FIG. 5, measuring the first frequency band of the UFA further includes the following sub-steps:

Step 021, generating signals by the signal generator 320 from a starting frequency.

Step 022, regulating the transmission power, and when one of the field strength probes 20 receives a signal, recording the present transmission power through the power meter 340, which should correspond to predetermined data, meanwhile displaying and recording data concerning the field strength of the received signal as read by the other field strength probes 20. In the present embodiment, the first frequency band is a low frequency band, with a range of 80 MHz-1000 MHz. The first frequency band can also be a high frequency band, with a range of 1 GHz-3 GHz.

Step 023, increasing the transmission frequency of the signal by a predetermined amount, such as 1% of the length of the first frequency band, until the upper limit of the first frequency band is reached.

Step 024, Recording the transmission power at different frequencies, and recording data as to the strength of signal read by each field strength probe 20, the strength of signal read by field strength probe 20 corresponds to the transmission power at different frequencies.

Step 025, changing the polarity of the antenna 200, which the antenna 200 is changed from the horizontal polarity to the vertical polarity or vice versa, thus changing the polarity of the signal.

Step 026, repeating from the sub-step 022 to the sub-step 025, to finish the UFA testing in the first frequency band with two polarities of the antenna 200.

Step 03, changing the antenna 200 for a UFA test in a second frequency band. In the present embodiment, if the first frequency band is a low frequency band, the second frequency band is a high frequency band. Thus the antenna 200 must be changed to a high frequency antenna. Correspondingly, when the first frequency band was a high frequency band, the second frequency band will be a low frequency band.

Step 04, measuring the UFA in the second frequency band. The sub-steps of measuring the UFA in the second frequency band are the same as those for the first frequency band.

Step 05, determining the results. According to the prior determination rules, when the amplitude of the signals received by 75% of the probe grid array is within the range of −0 dB˜+6 dB, the spread of the electromagnetic field strength for UFA purposes is considered uniform.

When using the UFA testing apparatus 100 to operate an electromagnetic radiation immunity UFA test, the plurality of field strength probes 20 are arranged on the testing rack 10 to form a probe grid array corresponding to the testing points of the UFA test. Thus the respective positions of the field strength probes 20 do not need to be changed, and frequent reversals of the polarity of the antenna 200 are not required, saving time and convenience.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A uniform field area (UFA) testing apparatus, comprising:
a testing rack; and
a plurality of field strength probes, mounted on the testing rack;
wherein the plurality of field strength probes are positioned on a vertical plane and forms a probe grid array corresponding to the testing points of the UFA test, the grid spacing of the probe grid array corresponds to the distance of the neighboring testing points of the UFA test.

2. The UFA testing apparatus of claim 1, wherein the plurality of field strength probes are detachably mounted on the testing rack.

3. The UFA testing apparatus of claim 1, wherein the testing rack includes a baseboard, two columns, and a plurality of bars, the two columns are mounted on the baseboard and are perpendicular to the baseboard, the plurality of bars are mounted spaced on the two columns at predetermined heights.

4. The UFA testing apparatus of claim 3, wherein the plurality of bars are equally spaced on the column at a predetermined distance, the distance corresponds to the distance of the neighboring testing points of the UFA test.

5. The UFA testing apparatus of claim 4, wherein the space between the distal ends of each bar detachably hold a field strength probe, the space between the distal end of the neighboring bars in the same height on different column corresponds to the distance of the neighboring testing points of the UFA test.

6. The UFA testing apparatus of claim 4, wherein the lowest bars being a predetermined height above the floor.

7. A UFA testing system, comprising:
a UFA testing apparatus, including a testing rack and a plurality of field strength probes mounted on the testing rack;
an antenna;
a computer, connected to the antenna;
a power meter, connected to the UFA testing apparatus;
a power amplifier, connected to the power meter;
a signal generator, connected to the power amplifier;
wherein the plurality of field strength probes are positioned on a vertical plane and form a probe grid array corresponding to the testing points of the UFA test, the antenna is aimed at the probe grid array, the signal generator generates signal in different transmit frequencies, the signal is transmitted to the plurality of field strength probes by the power amplifier, the power meter, and the antenna, the computer analyzes the data read by the plurality of field strength probes in different frequencies and determines whether the UFA has substantially uniformity.

8. The UFA testing system of claim 7, wherein the antenna aims at the plurality of field strength probes at horizontal polarity and vertical polarity respectively.

9. The UFA testing system of claim 7, wherein the transmission frequency includes a first frequency band and a second frequency band, when the first frequency band is a high frequency band, the second frequency band is a low frequency band; when the first frequency band is a low frequency band, the second frequency band is a high frequency band.

10. The UFA testing system of claim 9, wherein the low frequency band with a range of 80 MHz-1000 MHz, the high frequency band with a range of 1 GHz-3 GHz.

11. The UFA testing system of claim 9, wherein the antenna is spaced from the UFA testing apparatus of a predetermined distance.

12. A UFA testing method, comprising the following steps:
placing a UFA testing apparatus in a UFA, and ensuring a plurality of field strength probes are respectively positioned according to a corresponding the testing point of the UFA;
measuring the UFA in a first frequency band;
changing an antenna for a UFA test in a second frequency band;
measuring the UFA in the second frequency band;
determining the testing result.

13. The UFA testing method of claim 12, the step of measuring the UFA in the first and second frequency band further comprising:
transmitting a signal with predetermined antenna polarity to the probe grid array corresponding to the testing points of the UFA test;
regulating the transmission frequency, to make one of the field strength probe read a predetermined data, recording the present transmission power and the data read by each field strength probe;
increasing the transmission frequency until reaching the upper limit of the frequency band;
recording the transmission power corresponding to each frequency point and the data read by each field strength probe;
changing the polarity of the signal;
repeating the above steps.

14. The UFA testing method of claim 12, wherein when the first frequency band is a high frequency band, the second frequency band is a low frequency band; when the first frequency band is a low frequency band, the second frequency band is a high frequency band.

15. The UFA testing method of claim 14, wherein the low frequency band with a range of 80 MHz-1000 MHz, the high frequency band with a range of 1 GHz-3 GHz.
